(19) United States
(12) Patent Application Publication
(10) Pub. No.: US 2024/0125623 A1
(43) Pub. Date: Apr. 18, 2024

(54) MAGNETIC SCALE, MAGNETIC SCALE SYSTEM, METHOD FOR MANUFACTURING MAGNETIC SCALE, AND METHOD FOR MANUFACTURING MAGNETIC SCALE SYSTEM

(71) Applicant: Panasonic Intellectual Property Management Co., Ltd., Osaka (JP)

(72) Inventors: Takafumi TSUSHIMA, Osaka (JP); Kazuhiro ONAKA, Hyogo (JP)

(21) Appl. No.: 18/546,055

(22) PCT Filed: Feb. 15, 2022
(86) PCT No.: PCT/JP2022/006007

§ 371 Date: Aug. 10, 2023

(30) Foreign Application Priority Data
Feb. 18, 2021 (JP) 2021-024667

(51) Int. Cl. G01D 5/14

(52) U.S. Cl. CPC G01D 5/14

(57) ABSTRACT

A magnetic scale includes a magnetic scale body and an adhesive layer. The magnetic scale body includes a magnetic substance. The adhesive layer includes a hot-melt adhesive. The adhesive layer is attached to the magnetic scale body.

### TECHNICAL FIELD

The present disclosure generally relates to magnetic scales, magnetic scale systems, methods for manufacturing the magnetic scales, and methods for manufacturing the magnetic scale systems. The present disclosure specifically relates to a magnetic scale including a magnetic substance, a magnetic scale system, a method for manufacturing the magnetic scale, and a method for manufacturing the magnetic scale system.

### BACKGROUND ART

Patent Literature 1 describes a medium for magnetic scales (magnetic scale) formed by stacking a magnetic layer and a protective layer in this order on a non-magnetic support member. Moreover, a surface on an opposite side of the non-magnetic support member from the magnetic layer is laminated with a double-sided tape including an adhesive layer and a stripping sheet. The medium for magnetic scales are to be affixed via the double-sided tape to various kinds of apparatuses.

In the medium for magnetic scales (magnetic scale) described in Patent Literature 1, however, a vibration or the like may cause the stripping sheet (protection film) to fall off, and the strength of the medium against a disturbance such as the vibration may be unsatisfactory.

### CITATION LIST

### Patent Literature

Patent Literature 1: JP 2006-323935 A

### SUMMARY OF INVENTION

It is an object of the present disclosure to improve the strength of a magnetic scale.

A magnetic scale according to an aspect of the present disclosure includes a magnetic scale body and an adhesive layer. The magnetic scale body includes a magnetic substance. The adhesive layer includes a hot-melt adhesive. The adhesive layer is attached to the magnetic scale body.

A magnetic scale system according to an aspect of the present disclosure includes the magnetic scale and an adhesion target. The magnetic scale body is bonded to the adhesion target via the adhesive layer.

A method for manufacturing a magnetic scale according to an aspect of the present disclosure includes a step of attaching an adhesive layer including a hot-melt adhesive to at least part of a magnetic scale body including a magnetic substance.

A method for manufacturing a magnetic scale system according to an aspect of the present disclosure includes: all steps in the method for manufacturing the magnetic scale; and a step of melting the adhesive layer to make the adhesive layer adhere to an adhesion target and then coagulating the adhesive layer.

### BRIEF DESCRIPTION OF DRAWINGS

FIG. 1 is a side view of a magnetic scale and an adhesion target according to an embodiment;

FIG. 2 is a side view of a magnetic scale system including the magnetic scale and the adhesion target;

FIG. 3 is a side view of a magnetic scale according to a comparative example of the magnetic scale and an adhesion target; and

FIGS. 4A to 4C are side views of manufacturing steps of the magnetic scale according to the embodiment.

### DESCRIPTION OF EMBODIMENTS

A magnetic scale, a magnetic scale system, a method for manufacturing the magnetic scale, and a method for manufacturing the magnetic scale system according to an embodiment will be described below with reference to the drawings. Note that the embodiment described below is a mere example of various embodiments of the present disclosure. Various modifications may be made to the embodiment described below depending on design or the like as long as the object of the present disclosure is achieved. Moreover, figures described in the following embodiment are schematic views. The ratio of sizes and the ratio of thicknesses of components in the figures do not necessarily reflect actual dimensional ratios.

### EMBODIMENT

(Overview)

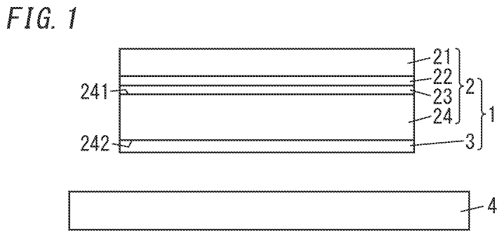

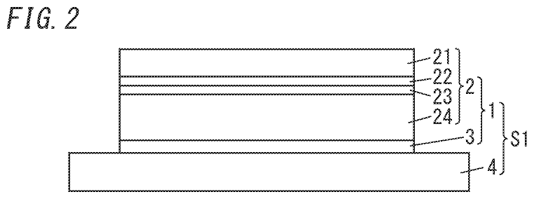

FIG. 1 is a view representing a magnetic scale 1 of the present embodiment and an adhesion target 4 which is a target to which the magnetic scale 1 is to be attached by bonding. The adhesion target 4 of the present embodiment is a substrate. The magnetic scale 1 is attached to the adhesion target 4, thereby forming a magnetic scale system S1 including the magnetic scale 1 and the adhesion target 4 As shown in FIG. 2. The magnetic scale system S1 is to be used together with a magnetic sensor. Magnetism generated at the magnetic scale 1 of the magnetic scale system S1 is detected by the magnetic sensor, thereby obtaining a relative position of the adhesion target 4 with respect to the magnetic sensor.

The magnetic scale 1 includes a magnetic scale body 2 and an adhesive layer 3. The magnetic scale body 2 includes a magnetic substance. The adhesive layer 3 includes a hot-melt adhesive. The adhesive layer 3 is attached to the magnetic scale body 2.

Heating the adhesive layer 3 melts the adhesive layer 3, thereby bonding the magnetic scale body 2 to the adhesion target 4 via the adhesive layer 3.

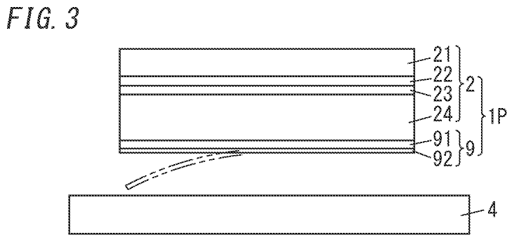

Here, FIG. 3 shows a view of a magnetic scale 1P according to a comparative example. The magnetic scale 1P according to the comparative example is different from the magnetic scale 1 according to the embodiment in that a double-sided tape 9 in place of the adhesive layer 3 is attached to a magnetic scale body 2. The double-sided tape 9 includes a sticking sheet 91 and a protection film 92. The sticking sheet 91 has a first surface bonded to the magnetic scale body 2 and a second surface covered with the protection film 92.

In the magnetic scale 1P according to the comparative example, applying vibration to the magnetic scale 1P, bringing the magnetic scale 1P into contact with another member, or the like may cause the protection film 92 to peel, and fall, off from the sticking sheet 91 as shown by the long dashed double-short dashed line in FIG. 3. Moreover, when the magnetic scale 1P is used in a high temperature environment such as in a tropical region, the adhesive force of the sticking sheet 91 may lower, and the protection film 92 may thus fall off from the sticking sheet 91. In contrast, the adhesive layer 3 of the magnetic scale 1 of the present embodiment requires no protection film 92 and thus has high resistance to the vibration or the like as compared with the magnetic scale 1P according to the comparative example. That is, according to the magnetic scale 1 of the present embodiment, the magnetic scale 1 has improved strength against the disturbance such as the vibration.

Moreover, as another comparative example, assume that an ultraviolet cure adhesive is used as the adhesive layer 3. The ultraviolet cure adhesive has to be applied immediately before the magnetic scale body 2 is bonded to the adhesion target 4. In contrast, in the magnetic scale 1 of the present embodiment, the adhesive layer 3 can be attached to the magnetic scale body 2 in advance, and therefore, the magnetic scale 1 has the advantage that man-hours of the step of bonding the magnetic scale body 2 to the adhesion target 4 can be reduced. Moreover, the magnetic scale 1 of the present embodiment has the advantage that a time required for the step of bonding the magnetic scale body 2 to the adhesion target 4 can be reduced as compared with the case where the ultraviolet cure adhesive is used.

As shown in FIG. 2, the magnetic scale system S1 includes the magnetic scale 1 and the adhesion target 4. The magnetic scale body 2 is bonded to the adhesion target 4 via the adhesive layer 3. More specifically, the adhesive layer 3 is melted and coagulated, and thereby, the magnetic scale body 2 is bonded to the adhesion target 4 via the adhesive layer 3.

Thus, the magnetic scale 1 bonded to the adhesion target 4 can be used.

(Details)

The magnetic scale 1 and the magnetic scale system S1 of the present embodiment will be described in further detail below. In the following description, the adhesive layer 3 is disposed downward of the magnetic scale body 2, and the magnetic scale body 2 is disposed upward of the adhesive layer 3. Note that these definitions are not intended to limit directions of use of the magnetic scale 1.

As shown in FIG. 1, the magnetic scale 1 includes the magnetic scale body 2 and the adhesive layer 3. The magnetic scale body 2 includes a magnetic layer 21, a base material 22, a sticking sheet 23 of a double-sided tape, and a support member 24. The magnetic scale system S1 include the magnetic scale 1 and the adhesion target 4.

The magnetic layer 21 includes a magnetic substance. The material for the magnetic layer 21 is, for example, a mixture of a powdery magnetic substance, a thermosetting resin, a hardener, and methyl ethyl ketone (MEK). The mixture is applied to the base material 22 and is cured by heating, thereby forming the magnetic layer 21. The magnetic layer 21 is stacked on the base material 22. The magnetic layer 21 is in the shape of, for example, a rectangular parallelepiped.

The material for the base material 22 is, for example, polyethylene terephthalate (PET). The base material 22 is in the shape of a sheet.

The sticking sheet 23 has an upper surface to which the base material 22 is bonded, and the sticking sheet 23 has a lower surface to which the support member 24 is bonded. Thus, the sticking sheet 23 bonds the base material 22 to the support member 24. Thus, the magnetic layer 21 is bonded to the support member 24 via the sticking sheet 23 and the base material 22. That is, the sticking sheet 23 bonds the magnetic layer 21 to the support member 24.

The material for the support member 24 is, for example, polycarbonate. The support member 24 is in the shape of, for example, a rectangular parallelepiped. The support member 24 has a first surface 241 and a second surface 242. The first surface 241 is a surface (upper surface) on one side in a thickness direction defined with respect to the support member 24. The second surface 242 is a surface (lower surface) on the other side in the thickness direction defined with respect to the support member 24. That is, the second surface 242 is a surface on an opposite side of the first surface 241.

The first surface 241 faces the magnetic layer 21. That is, the first surface 241 and the magnetic layer 21 are vertically aligned with each other, and the first surface 241 is closer to the magnetic layer 21 than the second surface 242 is. The support member 24 supports the magnetic layer 21.

The adhesive layer 3 is attached to the second surface 242 of the support member 24. The adhesive layer 3 includes the hot-melt adhesive. The material for the hot-melt adhesive is, as an example, ethylene vinyl acetate (EVA).

The magnetic scale body 2 and the adhesion target 4 are bonded to each other via the adhesive layer 3. That is, the adhesive layer 3 has an upper surface bonded to the magnetic scale body 2, and the adhesive layer 3 has a lower surface bonded to the adhesion target 4.

The adhesion target 4 is a substrate. More specifically, the adhesion target 4 is a printed circuit board. The material for the adhesion target 4 is, for example, a synthetic resin such as a polybutylene terephthalate (PBT) or polyphenylene sulfide (PPS), or metal such as aluminum.

Note that the adhesion target 4 is not necessarily limited to the substrate. The adhesion target 4 is an object which a user intends to use with the magnetic scale 1 attached thereto, and the adhesion target 4 is not particularly limited. The adhesion target 4 may be, for example, a motor, a member driven by a motor, or a member such as a brake pedal, a brake lever, or a shift lever of an automobile.

(Manufacturing Method)

Next, a method for manufacturing the magnetic scale 1 and the magnetic scale system S1 will be described. Note that the manufacturing method described below is a mere example, and the order of steps may accordingly be changed, or a step(s) may accordingly be added or omitted.

(Method for Manufacturing Magnetic Scale)

First, the method for manufacturing the magnetic scale 1 will be described. In the manufacturing method described below, a layered structure including the magnetic scale body 2 and the adhesive layer 3 is formed to have an area larger than the area of a single magnetic scale 1, and the layered structure is cut, thereby manufacturing a plurality of magnetic scales 1. Note that each magnetic scale 1 may individually be manufactured.

First, the base material 22 is prepared. Moreover, a mixture used as the material for the magnetic layer 21 is prepared. The mixture includes a magnetic substance, a thermosetting resin, a hardener, and methyl ethyl ketone (MEK).

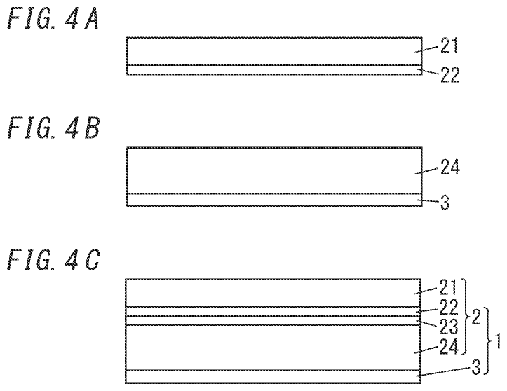

Next, the mixture is applied to the base material 22. Moreover, the mixture is heated. This cures the thermosetting resin, and as shown in FIG. 4A, the magnetic layer 21 is thus formed.

Next, the support member 24 is prepared. Moreover, as shown in FIG. 4B, the hot-melt adhesive (the adhesive layer 3) is applied to the support member 24. More specifically, the support member 24 is heated in advance, and the hot-melt adhesive is melted on the surface of the support member 24. Thus, the hot-melt adhesive adheres to the support member 24. Thereafter, the temperature of the hot-melt adhesive decreases, and thereby, the hot-melt adhesive coagulates. Thus, the adhesive layer 3 is formed on the surface (lower surface) of the support member 24.

That is, the method for manufacturing the magnetic scale 1 in the present embodiment includes a step of attaching the adhesive layer 3 including the hot-melt adhesive to at least part (support member 24) of the magnetic scale body 2 including the magnetic substance (magnetic layer 21). The step of attaching the adhesive layer 3 to the at least part (support member 24) of the magnetic scale body 2 includes melting the adhesive layer 3 to make the adhesive layer 3 adhere to the at least part (support member 24) of the magnetic scale body 2 and then coagulating the adhesive layer 3.

Then, the sticking sheet 23 is prepared. Further, as shown in FIG. 4C, the base material 22 is affixed to the support member 24 via the sticking sheet 23. That is, the base material 22 is bonded to the upper surface of the sticking sheet 23, and the support member 24 is bonded to the lower surface of the sticking sheet 23. Thus, the layered structure including the magnetic scale body 2 and the adhesive layer 3 is formed.

As explained above, the magnetic scale body 2 includes the magnetic layer 21 including the magnetic substance, the support member 24 supporting the magnetic layer 21, and the sticking sheet 23 bonding the magnetic layer 21 and the support member 24 to each other, and the method for manufacturing the magnetic scale 1 includes the following step. That is, the method for manufacturing the magnetic scale 1 includes the step of melting the adhesive layer 3 to make the adhesive layer 3 adhere to the support member 24 and then bonding the support member 24 to the base material 22 via the sticking sheet 23. In sum, the method for manufacturing the magnetic scale 1 includes the step of melting the adhesive layer 3 to make the adhesive layer 3 adhere to the support member 24 and then bonding the support member 24 to the magnetic layer 21 via the sticking sheet 23 (via the base material 22).

The adhesive layer 3 is melted to adhere to the support member 24, and then, the support member 24 is bonded to the base material 22 (magnetic layer 21) via the sticking sheet 23. Therefore, heat for melting the adhesive layer 3 is suppressed from reducing the viscosity of the sticking sheet 23.

Next, the layered structure is cut in the size of a single magnetic scale 1, thereby forming a plurality of magnetic scales 1. The step includes: a primary cutting step of cutting the layered structure in a first direction orthogonal to a stacking direction (up/down direction); and a secondary cutting step of cutting the layered structure in a second direction orthogonal to both the stacking direction and the first direction. Moreover, after the primary cutting step, and before the secondary cutting step, the magnetic layer 21 is magnetized. Moreover, whether or not the magnetic layer 21 is successfully magnetized is determined.

Through the steps described above, the plurality of magnetic scales 1 are manufactured. Each magnetic scale 1 is packed and shipped out. Each magnetic scale 1 is bonded to the adhesion target 4 at a shipment destination, and thereby, the magnetic scale 1 and the adhesion target 4 configure the magnetic scale system S1.

(Method for Manufacturing Magnetic Scale System)

Next, steps of manufacturing the magnetic scale system S1 will be described.

First, the magnetic scale 1 and the adhesion target 4 are prepared. Then, the adhesive layer 3 of the magnetic scale 1 is heated to melt the adhesive layer 3. Moreover, the adhesive layer 3 thus melted is made adhere to the adhesion target 4. Thereafter, the temperature of the adhesive layer 3 decreases, and the adhesive layer 3 thus coagulates. Thus, as shown in FIG. 2, the magnetic scale body 2 and the adhesion target 4 are bonded to each other via the adhesive layer 3. That is, the magnetic scale system S1 is formed.

As explained above, the method for manufacturing the magnetic scale system S1 in the present embodiment includes all the steps of the method for manufacturing the magnetic scale 1 and further includes the following step. That is, the step of melting the adhesive layer 3 to make the adhesive layer 3 adhere to the adhesion target 4 and then coagulating the adhesive layer 3. When the material for the adhesive layer 3 is ethylene vinyl acetate (EVA), the adhesive layer 3 is melted by heating to about 80 to 100° C.

Here, as an example, in the step of melting the adhesive layer 3, the adhesive layer 3 may be irradiated with a laser beam to melt the adhesive layer 3. In this method, the adhesive layer 3 can be locally heated, and therefore, the magnetic layer 21 is suppressed from being exposed to heat. This reduces defects in the magnetic scale body 2 caused by heat.

Moreover, as another example, in the step of melting the adhesive layer 3, the adhesion target 4 may be heated, and the adhesive layer 3 may be brought into contact with the adhesion target 4, thereby melting the adhesive layer 3. That is, the adhesive layer 3 may be melted by heat transmitted from the adhesion target 4 to the adhesive layer 3. For example, a lower surface of the adhesion target 4 is brought into contact with a hot plate, thereby heating the adhesion target 4. This method suppresses the magnetic layer 21 from being exposed to heat as compared with a case where the entirety of the magnetic scale 1 is heated. This reduces defects in the magnetic scale body 2 caused by heat.

### Variations of Embodiment

Variations of the embodiment will be enumerated below. The variations described below may be accordingly combined with each other.

The magnetic scale body 2 has to include neither the sticking sheet 23 nor the support member 24. That is, the adhesive layer 3 may be directly attached to the base material 22.

Alternatively, the magnetic scale body 2 does not have to include the base material 22. That is, the sticking sheet 23 may be directly bonded to the magnetic layer 21.

Alternatively, the magnetic scale body 2 has to include none of the base material 22, the sticking sheet 23, and the support member 24. That is, the adhesive layer 3 may be directly attached to the magnetic layer 21.

Before the adhesive layer 3 is made adhere to the adhesion target 4, a surface (upper surface), to which the adhesive layer 3 is made adhere, of the adhesion target 4 may be subjected to surface treatment. For example, a grave may be formed in the surface of the adhesion target 4, or the surface roughness of the surface of the adhesion target 4 may be increased (may be made coarse). This makes the adhesive layer 3 easily adhere to the surface of the adhesion target 4.

### SUMMARY

From the embodiment and the like explained above, the following aspects are disclosed.

A magnetic scale (1) of a first aspect includes a magnetic scale body (2) and an adhesive layer (3). The magnetic scale body (2) includes a magnetic substance. The adhesive layer (3) includes a hot-melt adhesive. The adhesive layer (3) is attached to the magnetic scale body (2).

With this configuration, heating the adhesive layer (3) melts the adhesive layer (3), which enables the magnetic scale body (2) to be bonded to the adhesion target (4) via the adhesive layer (3). Here, as a comparative example shown in FIG. 3, an example is assumed in which a double-sided tape (9) in place of the adhesive layer (3) is attached to a magnetic scale body (2). In the comparative example, a vibration or the like may cause a protection film (92) to fall off. In contrast, the adhesive layer (3) of the magnetic scale (1) of the present disclosure requires no protection film (92) and thus has high resistance to the vibration or the like as compared with the comparative example. That is, according to the magnetic scale (1) of the present disclosure, the magnetic scale (1) has improved strength against a disturbance such as the vibration.

In a magnetic scale (1) of a second aspect referring to the first aspect, the magnetic scale body (2) includes a magnetic layer (21) including the magnetic substance and a support member (24) supporting the magnetic layer (21). The support member (24) has a first surface (241) facing the magnetic layer (21) and a second surface (242) on an opposite side of the first surface (241). The adhesive layer (3) is attached to the second surface (242) of the support member (24).

With this configuration, the support member (24) is disposed between the magnetic layer (21) and the adhesive layer (3), and therefore, heat for melting the adhesive layer (3) is difficultly transmitted to the magnetic layer (21) as compared with a case where the adhesive layer (3) is directly attached to the magnetic layer (21). That is, the magnetic layer (21) can be protected from heat.

In a magnetic scale (1) of a third aspect referring to the second aspect, the magnetic scale body (2) further includes a sticking sheet (23). The sticking sheet (23) bonds the magnetic layer (21) to the support member (24).

With this configuration, the magnetic layer (21) and the support member (24) are bonded at low cost.

Configurations except for the configuration in the first aspect are not essential configurations for the magnetic scale (1) and may thus accordingly be omitted.

A magnetic scale system (S1) of a fourth aspect includes: the magnetic scale (1) of any one of the first to third aspects; and an adhesion target (4). The magnetic scale body (2) is bonded to the adhesion target (4) via the adhesive layer (3).

With this configuration, the magnetic scale system (S1) including the magnetic scale (1) and the adhesion target (4) integrally as one piece can be provided.

A method for manufacturing the magnetic scale (1) of a fifth aspect includes a step of attaching an adhesive layer (3) to at least part of a magnetic scale body (2). The adhesive layer (3) includes a hot-melt adhesive. The magnetic scale body (2) includes a magnetic substance.

This configuration enables strength of the magnetic scale (1) against a disturbance such as a vibration to be improved.

In a method for manufacturing the magnetic scale (1) of a sixth aspect referring to the fifth aspect, the step of attaching the adhesive layer (3) to the at least part of the magnetic scale body (2) includes melting the adhesive layer (3) to make the adhesive layer (3) adhere to the at least part of the magnetic scale body (2) and then coagulating the adhesive layer (3).

This configuration enables adhesive strength between the magnetic scale body (2) and the adhesive layer (3) to be increased.

In a method for manufacturing of a magnetic scale (1) of a seventh aspect referring to the fifth or sixth aspect, the magnetic scale body (2) includes a magnetic layer (21) including the magnetic substance, a support member (24) supporting the magnetic layer (21), and a sticking sheet (23) bonding the magnetic layer (21) and the support member (24) to each other. The method for manufacturing the magnetic scale (1) is a method for manufacturing the magnetic scale (1) including the magnetic scale body (2). The method for manufacturing the magnetic scale (1) further includes a step of melting the adhesive layer (3) to make the adhesive layer (3) adhere to the support member (24) and then bonding the support member (24) to the magnetic layer (21) via the sticking sheet (23).

With this configuration, heat for melting the adhesive layer (3) is suppressed from reducing the viscosity of the sticking sheet (23).

Configurations except for the configuration of the fifth aspect are not essential configurations for the method for manufacturing the magnetic scale (1) and may thus accordingly be omitted.

Moreover, a method for manufacturing a magnetic scale system (S1) of an eighth aspect includes: all steps in the method for manufacturing the magnetic scale (1) according to any one of the fifth to seventh aspects; and a step of melting the adhesive layer (3) to make the adhesive layer (3) adhere to an adhesion target (4) and then coagulating the adhesive layer (3).

With this configuration, the magnetic scale system (S1) including the magnetic scale (1) and the adhesion target (4) integrally as one piece can be manufactured.

In a method for manufacturing of a magnetic scale system (S1) of a ninth aspect referring to the eighth aspect, the step of melting the adhesive layer (3) includes irradiating the adhesive layer (3) with a laser beam to melt the adhesive layer (3).

With this configuration, the magnetic substance (magnetic layer (21)) of the magnetic scale body (2) is suppressed from being subjected to heat. This reduces defects in the magnetic scale body (2) caused by heat.

In a method for manufacturing of a magnetic scale system (S1) of a tenth aspect referring to the eighth aspect, the step of melting the adhesive layer (3) includes heating the adhesion target (4) and bringing the adhesive layer (3) into contact with the adhesion target (4) to melt the adhesive layer (3).

With this configuration, the magnetic substance (magnetic layer (21)) of the magnetic scale body (2) is suppressed from being subjected to heat. This reduces defects in the magnetic scale body (2) caused by heat.

Configurations except for the configuration in the eighth aspect are not essential configurations for the method for manufacturing the magnetic scale system (S1) and may thus accordingly be omitted.

The aspects described above should not be construed as limiting, and various configurations (including variations) of the magnetic scale (1) and the magnetic scale system (S1) according to the embodiment can be implemented by the method for manufacturing the magnetic scale (1) and the method for manufacturing the magnetic scale system (S1) respectively.

### REFERENCE SIGNS LIST

1 Magnetic Scale
2 Magnetic Scale Body
3 Adhesive Layer
4 Adhesion Target
21 Magnetic Layer
23 Sticking Sheet
24 Support Member
241 First Surface
242 Second Surface
S1 Magnetic Scale System

1. A magnetic scale comprising:
a magnetic scale body including a magnetic substance; and
an adhesive layer including a hot-melt adhesive and attached to the magnetic scale body.

2. The magnetic scale of claim 1, wherein
the magnetic scale body includes
a magnetic layer including the magnetic substance and
a support member supporting the magnetic layer,
the support member has
a first surface facing the magnetic layer and
a second surface on an opposite side of the first surface, and
the adhesive layer is attached to the second surface of the support member.

3. The magnetic scale of claim 2, wherein
the magnetic scale body further includes a sticking sheet bonding the magnetic layer and the support member to each other.

4. A magnetic scale system comprising:
the magnetic scale of claim 1; and
an adhesion target to which the magnetic scale body is bonded via the adhesive layer.

5. A method for manufacturing a magnetic scale, the method comprising a step of attaching an adhesive layer to at least part of a magnetic scale body,
the adhesive layer including a hot-melt adhesive,
the magnetic scale body including a magnetic substance.

6. The method of claim 5, wherein
the step of attaching the adhesive layer to the at least part of the magnetic scale body includes melting the adhesive layer to make the adhesive layer adhere to the at least part of the magnetic scale body and then coagulating the adhesive layer.

7. The method of claim 5, wherein
the magnetic scale includes the magnetic scale body including
a magnetic layer including the magnetic substance,
a support member supporting the magnetic layer, and
a sticking sheet bonding the magnetic layer and the support member to each other,
the method further comprising a step of melting the adhesive layer to make the adhesive layer adhere to the support member and then bonding the support member to the magnetic layer via the sticking sheet.

8. A method for manufacturing a magnetic scale system, the method comprising:
the step of attaching the adhesive layer to the at least part of the magnetic scale body according to claim 5; and
a step of melting the adhesive layer to make the adhesive layer adhere to an adhesion target and then coagulating the adhesive layer.

9. The method of claim 8, wherein
the step of melting the adhesive layer includes irradiating the adhesive layer with a laser beam to melt the adhesive layer.

10. The method of claim 8, wherein
the step of melting the adhesive layer includes heating the adhesion target and bringing the adhesive layer into contact with the adhesion target to melt the adhesive layer.

11. The method of claim 8, further comprising
the step of melting the adhesive layer to make the adhesive layer adhere to the support member and then bonding the support member to the magnetic layer via the sticking sheet according to claim 7.
